(19) United States
(12) Patent Application Publication
(10) Pub. No.: US 2010/0001252 A1
(43) Pub. Date: Jan. 7, 2010

(54) Resistance Changing Memory Cell

(76) Inventors: Ralf Symanczyk, Munich (DE); Rainer Bruchhaus, Sunnyvale, CA (US)

Correspondence Address: SLATER & MATSIL, L.L.P., 17950 PRESTON ROAD, SUITE 1000, DALLAS, TX, 75252, US

(21) Appl. No.: 12/166,021

(22) Filed: Jul. 1, 2008

(51) Int. Cl. H01L 45/00

(52) U.S. Cl. 257/4; 438/102; 257/E45.002

(57) ABSTRACT

An integrated circuit includes a plurality of programmable metallization memory cells. Each memory cell includes a memory element having a first electrode layer, a second electrode layer, and a resistance changing material layer arranged between the first electrode layer and the second electrode layer. The resistance changing material layer includes an active matrix material layer made of a chalcogenide material including at least one chalcogen and at least one electropositive element, wherein the chalcogenide material is not GeS, GeSe, AgSe or CuS.

### BACKGROUND

Integrated memory circuits including programmable metallization cells (PMC) are known. Programmable metallization cells are also known as CBRAM (conductive bridging random access memory) cells. These memory cells enable to store digital information by a resistive switching process. Programmable metallization memory cells include a resistance changing material having an electrochemically active material present in a volume between a first electrode (e.g., top electrode) and a second electrode (e.g., bottom electrode) which may be switched between different electric resistance values by bipolar electric pulsing. The switching process is based in principle on the fact that, by applying appropriate current pulses or voltage pulses of specific intensity and duration at the electrodes, elements of a so-called deposition cluster continue to increase in volume in the material positioned between the electrodes until the two electrodes are finally electrically bridged, i.e., are electrically connected with each other, which corresponds to the conductive state of the memory cell.

By applying correspondingly inverse current or voltage pulses, this process may be reversed again, so that the corresponding memory cell can be returned to a non-conductive state. In this way, a digital response between a state with a higher conductivity of the memory cell and a state with a lower conductivity of the memory cell may be achieved. Since the switching process is dependent on applying appropriate current or voltage pulses, the memory cell remains in either the conductive state or the non-conductive state, when no current pulses or voltage pulses are applied. The memory cell is therefore a so-called non-volatile memory cell.

In the simplest embodiment, such a memory cell may be switched between a very high resistance value (e.g., in the GOhm range) and a distinctly lower resistance value (e.g., in the kOhm range) by applying short current or voltage pulses. The memory cells may also be arranged as multi level memory cells, i.e., be capable of adapting more than two resistance values (each resistance value corresponds to one memory state). The switching process in the memory cell is substantially based on the modulation of the chemical composition and the local nanostructure of the resistance changing material including an electrochemically active material doped with a metal which serves as a solid body electrolyte and a diffusion matrix. The electrochemically active material is commonly a so-called chalcogenide material of germanium (Ge), selenium (Se), copper (Cu), sulphur (S), and/or silver (Ag), for instance, a GeSe, GeS, AgSe, or CuS compound. The pure chalcogenide material typically has a semiconducting behavior and has a very high electric resistance at room temperature, said electric resistance being by magnitudes, i.e., decimal powers of the ohmic resistance value higher than that of an electron-conductive metal. By the current or voltage pulses applied via the electrodes, the steric arrangement and the local concentration of the mobile doping element in the diffusion matrix is modified. Due to that, the so-called bridging, i.e., an electrical bridging of the volume between the electrodes of metal-rich depositions, may be caused, which modifies the electrical resistance of the programmable metallization memory cell by several magnitudes such that the ohmic resistance value is reduced by several decimal powers.

It is desirable to provide methods of manufacturing integrated circuits having programmable metallization memory cells which guarantee high reproducibility. Further, it is desirable to provide integrated circuits having programmable metallization memory cells which can be manufactured with high reproducibility.

### SUMMARY OF THE INVENTION

According to one embodiment of the present invention, an integrated circuit including a plurality of programmable metallization memory cells is provided. Each memory cell includes a memory element having a first electrode layer, a second electrode layer, and a resistance changing material layer being arranged between the first electrode layer and the second electrode layer. The resistance changing material layer includes an active matrix material layer made of a chalcogenide material including at least one chalcogen and at least one electropositive element, wherein the chalcogenide material is not GeS, GeSe, AgSe or CuS.

According to another embodiment of the present invention, a method of manufacturing an integrated circuit includes a plurality of programmable metallization memory cells. Each memory cell includes a memory element having a first electrode layer, a second electrode layer, and a resistance changing material layer arranged between the first electrode layer and the second electrode layer. The resistance changing material layer includes an active matrix material layer made of a chalcogenide material including at least one chalcogen and at least one electropositive element, wherein the chalcogenide material is not GeS, GeSe, AgSe or CuS. The method includes forming the first electrode, forming the active matrix material layer, and forming the second electrode.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic cross-sectional view of a solid electrolyte memory cell according to one embodiment of the present invention;

FIG. 1B shows a schematic cross-sectional view of a stack of solid electrolyte memory cells being part of an integrated circuit according to one embodiment of the present invention;

FIG. 2A shows a schematic cross-sectional view of a solid electrolyte memory cell according to one embodiment of the present invention which has been set to a first memory state;

FIG. 2B shows a schematic cross-sectional view of a solid electrolyte memory cell according to one embodiment of the present invention which has been set to a second memory state;

FIG. 3A shows a schematic drawing of a part of an integrated circuit including solid electrolyte memory cells according to one embodiment of the present invention;

FIG. 3B shows a schematic drawing of a part of an integrated circuit including solid electrolyte memory cells according to one embodiment of the present invention;

FIG. 4 shows a schematic drawing of an integrated circuit including resistance changing memory cells solid electrolyte memory cells according to one embodiment of the present invention;

FIG. 5A shows a schematic perspective view of a memory module according to one embodiment of the present invention;

FIG. 5B shows a schematic perspective view of a memory module according to one embodiment of the present invention; and

FIG. 6 shows a flow chart of a method of manufacturing a resistance changing memory cell according to one embodiment of the present invention.

### DETAILED DESCRIPTION OF ILLUSTRATIVE EMBODIMENTS

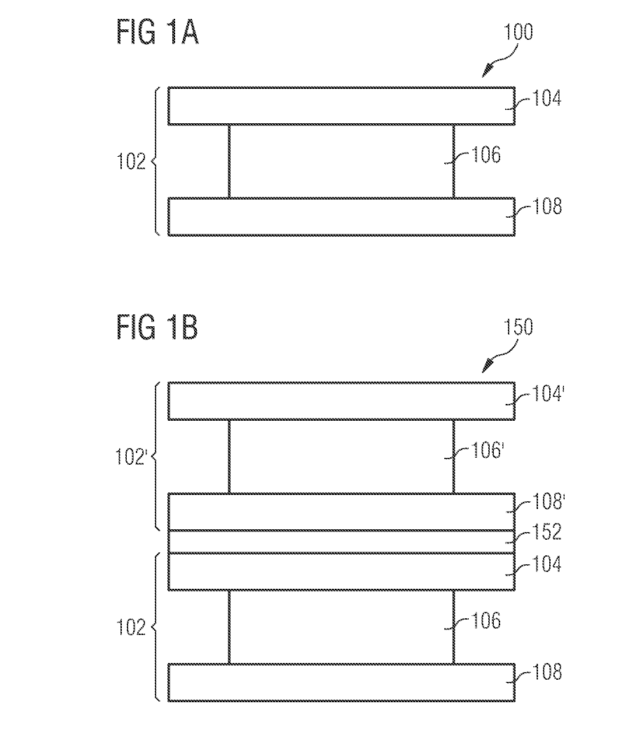

FIG. 1 shows a programmable metallization memory cell 100 according to one embodiment of the present invention. The memory cell 100 includes a stack of layers 102 including a first electrode 104, a resistance changing material layer 106 (also referred to as solid electrolyte block or ion conductor block) including an active matrix material layer made of a chalcogenide material including at least one chalcogen and at least one electropositive element, wherein the chalcogenide material is not germanium-sulfide (GeₓS_{y}), germanium-selenide (GeₓSe_{y}), silver-selenide (AgₓSe_{y}), copper-sulfide (CuₓS_{y}), arsenium-sulfide (AsₓS_{y}), or tungsten-oxide (WₓO_{y}), and a second electrode 108 which are stacked above each other in this order.

As can be derived from FIG. 1B, two memory cells 100 (i.e., two stacks of layers 102, 102′) may be arranged above each other, thereby obtaining a stack of memory cells 150. An integrated circuit having a plurality of stacks of memory cells 150 has a higher memory density, compared to “normal” integrated circuits having only memory cells shown in FIG. 1A.

The stack of layers 150 includes a first memory cell (stack of layers 102) and a second memory cell (stack of layers 102′), wherein the first memory cell comprises a first electrode layer 108, a second electrode layer 104 being arranged above the first electrode layer 108, and a first resistance changing material layer 106 being arranged between the first electrode layer 108 and the second electrode layer 104, and wherein the second memory cell 102′ comprises a third electrode layer 108′ being arranged above the second electrode layer 104, a fourth electrode layer 104′ being arranged above the third electrode layer 108′, and a second resistance changing material layer 106′ being arranged between the third electrode layer 108′ and the fourth electrode layer 104′.

An insulating layer 152, like a dielectric layer, is arranged between the second electrode layer 104 and the third electrode layer 108′. The insulating layer 152 may also be omitted, i.e., the second electrode layer 104 and the third electrode layer 108′ may be in direct contact with each other. Each of the electrode layers 104, 108, 104′ and 108′ may be connected to an individual terminal via which currents/voltages are applied to the memory cells. Alternatively, some of the terminals may be omitted. For example, if the second electrode layer 104 and the third electrode layer 108′ are in direct contact with each other, the second electrode layer 104 and the third electrode layer 108′ may share a common terminal. Also other architectures of stacked memory cells (e.g., three or more memory cells stacked above each other) are possible.

Due to the materials used for the resistance changing material layer 106 (high temperature proved material), it is possible to from a second memory cell (stack of layers 102′) over the first memory cell (stack of layers 102) without damaging the first memory cell due to high temperatures needed for manufacturing the second memory cell.

At least one electropositive element may be a metal or metalloid. The at least one electropositive material may be a metal selected from the group consisting of silver (Ag), gallium (Ga), copper (Cu), chromium (Cr), cobalt (Co), zinc (Zn), cadmium (Cd), bismuth (Bi), palladium (Pd) and platinum (Pt). The at least one chalcogen may be selected from the group consisting of sulphur (S), selenium (Se) or tellurium (Te). At least one chalcogen may be sulphur (S). The matrix material layer may be made of a material selected from the group consisting of AgGaS₂, CuGaS₂, AgCrS₂, CuCrS₂, Ga₂S₃, CoS, ZnS, CdS, Bi₂S₃, PdS, PtS or a combination thereof. The matrix material layer may be thermally stable at temperatures of up to 430° C., up to 450° C., up to 500° C. or up to 600° C. The matrix material layer may be doped with alkaline, alkaline earth and/or metal ions. The matrix material layer may be doped with silver (Ag), zinc (Zn) and/or copper (Cu) ions.

A plurality of programmable metallization memory cells 100 as described above may be interconnected in order to form an integrated circuit according to one embodiment of the present invention.

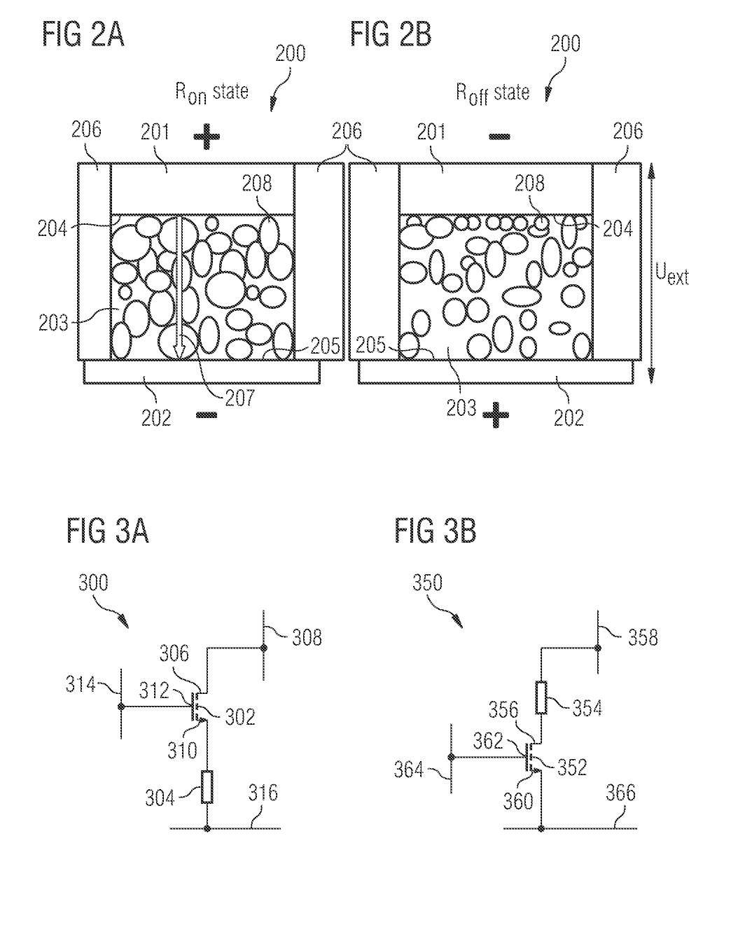

FIGS. 2A and 2B show a CBRAM cell 200 as an example of a programmable metallization memory cell according to one embodiment of the present invention.

As shown in FIG. 2A, the CBRAM cell 200 includes a first electrode 201, a second electrode 202, and a resistance changing material 203 which includes the electrochemically active material and which is sandwiched between the first electrode 201 and the second electrode 202.

The resistance changing material 203 may also be shared between a plurality of memory cells (not shown here), i.e., may form a continuous layer shared between a plurality of memory cells of an integrated circuit.

Here, the first electrode 201 directly contacts a first surface 204 of the resistance changing material 203, and the second electrode 202 directly contacts a second surface 205 of the resistance changing material 203. However, also intermediate layers may be interposed between the resistance changing material 203 and the first electrode 201 and/or between the resistance changing material 203 and the second electrode 202.

The resistance changing material 203 is isolated against its environment by an insulation structure 206.

Here, the first surface 204 is the top surface and the second surface 205 the bottom surface of the resistance changing material 203. In the same way, the first electrode 201 is the top electrode, and the second electrode 202 the bottom electrode of the CBRAM cell.

One of the first electrode 201 and the second electrode 202 may be a reactive electrode, the other one an inert electrode. Here, it is assumed that the first electrode 201 is the reactive electrode, and that the second electrode 202 is the inert electrode. In this case, the first electrode 201 for example includes silver (Ag), and the resistance changing material 203, for example, includes a silver-doped chalcogenide material including at least one chalcogen and at least one electropositive element, wherein the chalcogenide material is not germanium-sulfide (GeₓS_{y}), germanium-selenide (GeₓSe_{y}), silver-selenide (AgₓSe_{y}), copper-sulfide (CuₓS_{y}), arsenium-sulfide (AsₓS_{y}), or tungsten-oxide (WₓO_{y}), the second electrode 202 includes tungsten (W), and the insulation structure 206 includes SiO₂ or Si₃N₄. The present invention is however not restricted to these electrode, doping and insulation materials.

The first electrode 201 may alternatively or additionally include copper (Cu) or zinc (Zn), and the resistance changing material layer 203 may alternatively or additionally include copper-doped chalcogenide material including at least one chalcogen and at least one electropositive element, wherein the chalcogenide material is not germanium-sulfide (GeₓS_{y}), germanium-selenide (GeₓSe_{y}), silver-selenide (AgₓSe_{y}), copper-sulfide (CuₓS_{y}), arsenium-sulfide (AsₓS_{y}), or tungsten-oxide (WₓO_{y}).

The second electrode 202 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned materials, and can also include alloys of the afore-mentioned materials.

The thickness of the first electrode 201 (reactive electrode) may, for example, range between 5 nm and 500 nm, between 10 nm and 150 nm, or between 10 nm and 100 nm.

The thickness of the second electrode 202 (inert electrode) may, for example, range between 5 nm and 500 nm, between 15 nm and 150 nm, or between 25 nm and 100 nm.

It is to be understood that the embodiments of the present invention are not restricted to the above-mentioned electrode materials and thicknesses.

The thickness of the resistance changing material layer 203 may range between 5 nm and 500 nm, between 15 and 150 nm, or between 20 and 100 nm.

In the following, it is assumed that the first electrode 201 comprises or consists of silver (Ag). If a voltage as indicated in FIG. 2A is applied across the resistance changing material layer 203, a redox reaction is initiated which drives Ag⁺ ions out of the first electrode 201 into the resistance changing material layer 203 where they are reduced to Ag, thereby forming Ag rich clusters 208 within the resistance changing material layer 203. If the voltage applied across the resistance changing material layer 203 is applied for an enhanced period of time, the size and the number of Ag rich clusters within the resistance changing material layer 203 is increased to such an extent that a conductive bridge 207 between the first electrode 201 and the second electrode 202 is formed. In case that a voltage is applied across the resistance changing material 203 as shown in FIG. 2B (inverse voltage compared to the voltage applied in FIG. 2A), a redox reaction is initiated which drives Ag⁺ ions out of the resistance changing material layer 203 into the first electrode 201 where they are reduced to Ag. As a consequence, the size and the number of Ag rich clusters within the resistance changing material layer 203 is reduced, thereby erasing the conductive bridge 207. After having applied the voltage/inverse voltage, the memory cell 200 remains within the corresponding defined switching state even if the voltage/inverse voltage has been removed.

In order to determine the current memory status of a CBRAM cell, for example a sensing current may be routed through the CBRAM cell. The sensing current experiences a high resistance in case no conductive bridge 207 exists within the CBRAM cell, and experiences a low resistance in case a conductive bridge 207 exists within the CBRAM cell. A high resistance may, for example, represent “0”, whereas a low resistance represents “1”, or vice versa. The memory status detection may also be carried out using sensing voltages. Alternatively, a sensing voltage may be used in order to determine the current memory status of a CBRAM cell.

Programmable metallization memory cells according to embodiments of the present invention may be used together with a transistor, diode, or other active component for selecting the memory cell. FIG. 3A shows a schematic representation of such a memory cell that uses a resistance changing memory element. The memory cell 300 includes a select transistor 302 and a programmable metallization memory element 304. The select transistor 302 includes a source 306 that is connected to a bit line 308, a drain 310 that is connected to the memory element 304, and a gate 312 that is connected to a word line 314. The programmable metallization memory element 304 also is connected to a common line 316, which may be connected to ground, or to other circuitry, such as circuitry (not shown) for determining the resistance of the memory cell 300, for use in reading. Alternatively, in some configurations, circuitry (not shown) for determining the state of the memory cell 300 during reading may be connected to the bit line 308. It should be noted that as used herein the terms connected and coupled are intended to include both direct and indirect connection and coupling, respectively.

To write to the memory cell 300, the word line 314 is used to select the memory cell 300, and a current (or voltage) pulse on the bit line 308 is applied to the programmable metallization memory element 304, changing the resistance of the programmable metallization memory element 304. Similarly, when reading the memory cell 300, the word line 314 is used to select the cell 300, and the bit line 308 is used to apply a read voltage (or current) across the programmable metallization memory element 304 to measure the resistance of the programmable metallization memory element 304.

The memory cell 300 may be referred to as a 1T1J cell, because it uses one transistor, and one memory junction (the programmable metallization memory element 304). Typically, a memory device will include an array of many such cells. It will be understood that other configurations for a 1T1J memory cell, or configurations other than a 1T1J configuration may be used with a resistance changing memory element. For example, in FIG. 3B, an alternative arrangement for a 1T1J memory cell 350 is shown, in which a select transistor 352 and a programmable metallization memory element 354 have been repositioned with respect to the configuration shown in FIG. 3A. In this alternative configuration, the programmable metallization memory element 354 is connected to a bit line 358, and to a source 356 of the select transistor 352. A drain 360 of the select transistor 352 is connected to a common line 366, which may be connected to ground, or to other circuitry (not shown), as discussed above. A gate 362 of the select transistor 352 is controlled by a word line 364.

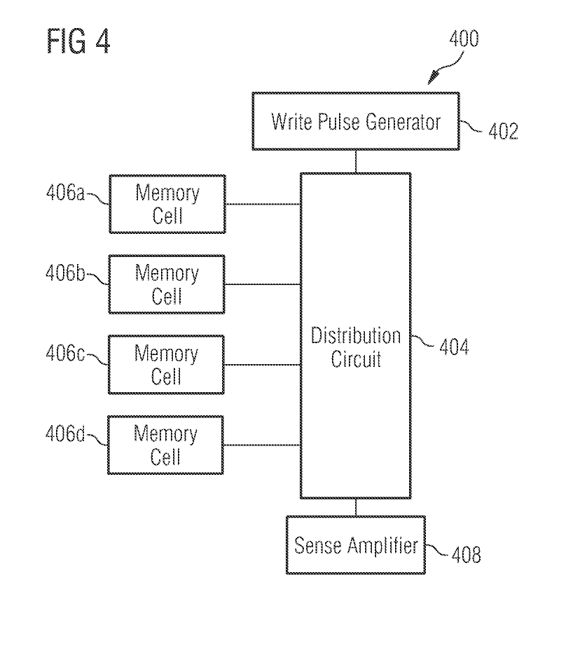

FIG. 4 illustrates a block diagram of a memory device 400 including a write pulse generator 402, a distribution circuit 404, programmable metallization memory cells (PMCs) 406a, 406b, 406c, 406d (for example programmable metallization memory cells 100 as shown in FIG. 1), and a sense amplifier 408. The write pulse generator 402 may generate current pulses voltage pulses that are supplied to the programmable metallization memory cells (PMCs) 406a, 406b, 406c, 406d via the distribution circuit 404, thereby programming the memory states of the programmable metallization memory cells (PMCs) 406a, 406b, 406c, 406d. The distribution circuit 404 may include a plurality of transistors that supply direct current pulses or direct voltage pulses to the programmable metallization memory cells (PMCs) 406a, 406b, 406c, 406d.

As already indicated, the electrochemically active material of the programmable metallization memory cells (PMCs) 406a, 406b, 406c, 406d may be changed from the non-conductive state to the conductive state (or vice versa) under the influence of current or voltage pulses. For example, a bit value “0” may be assigned to the non-conductive state, and a bit value “1” may be assigned to the electro-conductive state. Since different degrees of conductivity imply different electrical resistances, the sense amplifier 404 is capable of determining the memory state of one of the programmable metallization memory cells 406a, 406b, 406c, or 406d in dependence on the resistance of the electrochemically active material.

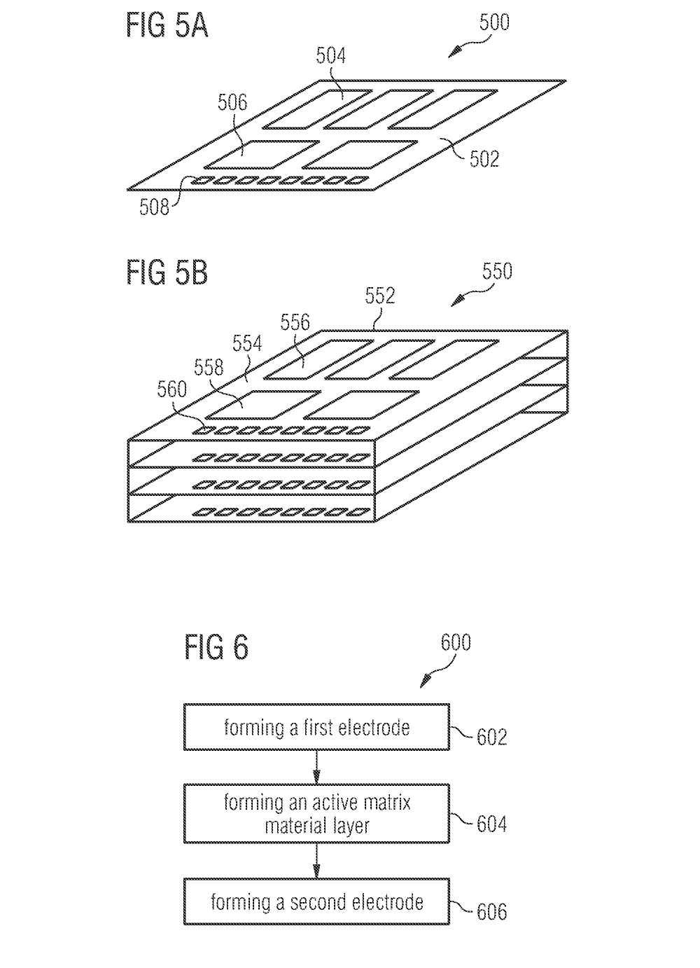

As shown in FIGS. 5A and 5B, memory cells according to embodiments of the present invention such as the programmable metallization memory cells 100 or 200 may be used in modules. In FIG. 5A, a memory module 500 is shown, on which one or more integrated circuits 504 in accordance with an embodiment of the invention are arranged on a substrate 502. The integrated circuits 504 may include numerous memory cells in accordance with an embodiment of the invention like the programmable metallization memory cells 100 or 200. The memory module 500 may also include one or more electronic devices 506, which may include memory, processing circuitry, control circuitry, addressing circuitry, bus interconnection circuitry, or other circuitry or electronic devices that may be combined on a module with a memory device, such as the integrated circuits 504. Additionally, the memory module 500 includes multiple electrical connections 508, which may be used to connect the memory module 500 to other electronic components, including other modules.

As shown in FIG. 5B, these modules may be stackable, to form a stack 550. For example, a stackable memory module 552 may contain one or more integrated circuits 556 in accordance with an embodiment of the invention, arranged on a stackable substrate 554. The integrated circuits 556 may contain memory cells as described above like the memory cells 100 or 200. The stackable memory module 552 may also include one or more electronic devices 558 which may include memory, processing circuitry, control circuitry, addressing circuitry, bus interconnection circuitry, or other circuitry or electronic devices that may be combined on a module with a memory device, such as the integrated circuits 556. Electrical connections 560 are used to connect the stackable memory module 552 with other modules in the stack 550, or with other electronic devices. Other modules in the stack 550 may include additional stackable memory modules, similar to the stackable memory module 552 described above, or other types of stackable modules, such as stackable processing modules, control modules, communication modules, or other modules containing electronic components

The present invention further relates to a method of manufacturing an integrated circuit according to one embodiment of the present invention including a plurality of programmable metallization memory cells, each memory cell including a memory element including a first electrode layer, a second electrode layer, and a resistance changing material layer being arranged between the first electrode layer and the second electrode layer, wherein the resistance changing material layer including an active matrix material layer made of a chalcogenide material including at least one chalcogen and at least one electropositive element, wherein the chalcogenide material is not germanium-sulfide (GeₓS_{y}), germanium-selenide (GeₓSe_{y}), silver-selenide (AgₓSe_{y}), copper-sulfide (CuₓS_{y}), arsenium-sulfide (AsₓS_{y}), or tungsten-oxide (WₓO_{y}) e.g., the memory cells 100 or 200. An example of such a method 600 is shown in FIG. 6. At 602, a first electrode layer is formed. At 604, an active matrix material layer is formed. At 606, a second electrode is formed.

The manufacturing method 600 may further include a doping process of the matrix material layer which is carried out after having formed the matrix material layer, and which introduces a mobile doping agent into the matrix material layer. The mobile doping agent may be selected from the group consisting of silver (Ag), zinc (Zn) and copper (Cu) or a combination thereof. The mobile doping agent may be provided by an additional doping layer formed on the matrix material layer, and the doping may be carried out after having formed the doping layer. The mobile doping agent may be provided by one of the first electrode layer and the second electrode layer, and the doping may be performed after having formed the second electrode. The active matrix material layer may be doped by diffusing the mobile doping agent into the active matrix material layer by exposing the active matrix material layer to heat. The heat exposition may include exposing the active matrix material layer to temperatures of about 250-600° C. The active matrix material layer may be doped by co-sputtering the mobile doping agent during sputtering of the active matrix material layer. The active matrix material layer may be doped by depositing a multi-layer structure including interchanging layers of doping agent material and active matrix material. The active matrix material layer may be doped by processing a multi-layer stack consisting of alternating layers of active matrix material and doping agent layers. The active matrix material layer may be doped by diffusing the mobile doping agent into the active matrix material layer by exposition to UV light irradiation. The active matrix material layer may be formed on the first electrode by a reactive sputtering method, plasma enhanced chemical vapour deposition (PECVD) or metalorganic chemical vapour deposition (MOCVD). The active matrix material layer may be formed in accordance with one embodiment of the present invention has a thickness of about 20-100 nm.

The present invention further provides a method of manufacturing an integrated circuit in accordance with an embodiment of the present invention (e.g., the method 600), wherein the method includes a CMOS BEOL (complementary-metal-oxide-semiconductor back-end-of-the-line) process to form a wiring structure above the plurality of programmable metallization memory cells which interconnects the plurality of programmable metallization memory cells with each other.

The CMOS BEOL process may be carried out at temperatures of about 400° C.-600° C. These temperatures are possible due to the kind of resistance changing material used. Normally, due to the fact that the active matrix material is commonly made of chalcogenides of germanium, e.g., GeS or GeSe, such high temperatures are not possible since the electrical and mechanical characteristics of the active matrix material such as specific resistance, ion conductivity and expansion coefficient, are negatively impacted by undesired chemical reactions and diffusion processes. This can lead to a large number of defects in the memory element comprising the programmable metallization memory cells. However, due to the properties of the active matrix material of the memory cells according to embodiments of the present invention, it is possible to use standard CMOS BEOL (complementary-metal-oxide-semiconductor back-end-of-the-line) process flows when manufacturing the programmable metallization memory cells since they are able to withstand temperatures of about 430° C., preferably 450° C., without losing their integrity.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising a plurality of programmable metallization memory cells, each memory cell comprising:
a first electrode layer;
a second electrode layer; and
a resistance changing material layer arranged between the first electrode layer and the second electrode layer, wherein the resistance changing material layer comprises an active matrix material layer made of a chalcogenide material comprising at least one chalcogen and at least one electropositive element, wherein the chalcogenide material is not germanium-sulfide (GeₓS_{y}), germanium-selenide (GeₓSe_{y}), silver-selenide (AgₓSe_{y}), copper-sulfide (CuₓS_{y}), arsenium-sulfide (AsₓS_{y}), or tungsten-oxide (WₓO_{y}).

2. The integrated circuit according to claim 1, wherein the electropositive element comprises a metal or metalloid.

3. The integrated circuit according to claim 1, wherein the electropositive element comprises a metal selected from the group consisting of silver (Ag), gallium (Ga), copper (Cu), chromium (Cr), cobalt (Co), zinc (Zn), cadmium (Cd), bismuth (Bi), palladium (Pd) and platinum (Pt).

4. The integrated circuit according to claim 1, wherein the chalcogen is selected from the group consisting of sulphur (S), selenium (Se) or tellurium (Te).

5. The integrated circuit according to claim 1, wherein the matrix material layer comprises a material selected from the group consisting of AgGaS₂, CuGaS₂, AgCrS₂, CuCrS₂, Ga₂S₃, CoS, ZnS, CdS, Bi₂S₃, PdS, PtS or a combination thereof.

6. The integrated circuit according to claim 1, wherein the matrix material is thermally stable at temperatures of up to 430° C.

7. The integrated circuit according to claim 1, wherein the matrix material is thermally stable at temperatures of up to 600° C.

8. The integrated circuit according to claim 1, wherein the matrix material layer is doped with alkaline, alkaline earth or metal ions.

9. The integrated circuit according to claim 1, wherein the matrix material layer is doped with silver (Ag), zinc (Zn) or copper (Cu) ions.

10. The integrated circuit according to claim 1, wherein the matrix material layer has a thickness of about 20 nm to about 100 nm.

11. The integrated circuit according to claim 1, wherein the plurality of programmable metallization memory cells are stacked above each other.

12. The integrated circuit according to claim 1, wherein the plurality of programmable metallization memory cells includes a first memory cell and a second memory cell, wherein the first memory cell comprises a first electrode layer, a second electrode layer arranged above the first electrode layer, and a first resistance changing material layer arranged between the first electrode layer and the second electrode layer, and wherein the second memory cell comprises a third electrode layer arranged above the second electrode layer, a fourth electrode layer being arranged above the third electrode layer, and a second resistance changing material layer being arranged between the third electrode layer and the fourth electrode layer.

13. A memory module comprising a plurality of integrated circuits according to claim 1.

14. A programmable metallization memory cell comprising:
a first electrode layer;
a second electrode layer; and
a resistance changing material layer being arranged between the first electrode layer and the second electrode layer, wherein the resistance changing material layer comprises an active matrix material layer made of a chalcogenide material comprising at least one chalcogen and at least one electropositive element, wherein the chalcogenide material is not germanium-sulfide (GeₓS_{y}), germanium-selenide (GeₓSe_{y}), silver-selenide (AgₓSe_{y}), copper-sulfide (CuₓS_{y}), arsenium-sulfide (AsₓS_{y}), or tungsten-oxide (WₓO_{y}).

15. A method of manufacturing an integrated circuit comprising a plurality of programmable metallization memory cells, each memory cell comprising a memory element comprising a first electrode layer, a second electrode layer, and a resistance changing material layer arranged between the first electrode layer and the second electrode layer, wherein the resistance changing material layer comprises an active matrix material layer made of a chalcogenide material comprising at least one chalcogen and at least one electropositive element, wherein the chalcogenide material is not germanium-sulfide (GeₓS_{y}), germanium-selenide (GeₓSe_{y}), silver-selenide (AgₓSe_{y}), copper-sulfide (CuₓS_{y}), arsenium-sulfide (AsₓS_{y}), or tungsten-oxide (WₓO_{y}), the method comprising:
forming the first electrode of each memory element;
forming the active matrix material layer of each memory element; and
forming the second electrode of each memory element.

16. The method according to claim 15, further comprising performing a doping process of the matrix material layer after forming the active matrix material layer, the doping process introducing a mobile doping agent into the matrix material layer.

17. The method according to claim 16, wherein the mobile doping agent comprises silver (Ag), zinc (Zn) or copper (Cu) or a combination thereof.

18. The method according to claim 16, wherein the mobile doping agent is provided by an additional doping layer formed on the matrix material layer, and wherein the doping is carried out after having formed the doping layer.

19. The method according to claim 16, wherein the mobile doping agent is provided by first electrode layer or the second electrode layer, and wherein the doping is performed after having formed the second electrode.

20. The method according to claim 16, wherein the active matrix material layer is doped by diffusing the mobile doping agent into the active matrix material layer by exposition to heat.

21. The method according to claim 16, wherein the active matrix material layer is doped by diffusing the mobile doping agent into the active matrix material layer by exposition to temperatures of about 250-600° C.

22. The method according to claim 16, wherein the active matrix material layer is doped by diffusing the mobile doping agent into the active matrix material layer by exposition to UV light irradiation.

23. The method according to claim 15, further comprising doping the matrix material layer, wherein the active matrix material layer is doped by co-sputtering the mobile doping agent during the sputtering of the active matrix material layer.

24. The method according to claim 15, further comprising doping the matrix material layer, wherein the active matrix material layer is doped by depositing a multi-layer structure comprising interchanging layers of doping agent material and active matrix material.

25. The method according to claim 15, wherein the active matrix material layer is formed on the first electrode by a reactive sputtering method, plasma enhanced chemical vapor deposition (PECVD) or metalorganic chemical vapor deposition (MOCVD).

26. The method according to claim 15, wherein the method comprises a CMOS BEOL process to form a wiring structure above the plurality of programmable metallization memory cells, the wiring structure interconnecting the plurality of programmable metallization memory cells with each other.

27. The method according to claim 26, wherein the CMOS BEOL process is carried out a temperatures of about 400-600° C.
